(19) United States
(12) Patent Application Publication
(10) Pub. No.: US 2020/0022868 A1
(43) Pub. Date: Jan. 23, 2020

(54) ANCILLARY UNIT

(71) Applicant: BROSE FAHRZEUGTEILE GMBH & CO. KOMMANDITGESELLSCHAFT, BAMBERG, Bamberg (DE)

(72) Inventors: Peter HORN, Kemmern (DE); Thomas WEINGAERTNER, Lichteneiche (DE); Alexander MUELLER, Bischberg (DE)

(73) Assignee: BROSE FAHRZEUGTEILE GMBH & CO. KOMMANDITGESELLSCHAFT, BAMBERG, Bamberg (DE)

(21) Appl. No.: 16/338,053

(22) PCT Filed: Oct. 9, 2017
(86) PCT No.: PCT/EP2017/075644

§ 371 Date: Mar. 29, 2019

(30) Foreign Application Priority Data
Oct. 10, 2016 (DE) 10 2016 219 635.9

(51) Int. Cl. A61H 23/02; B60N 2/90; A61H 1/00; H05K 7/14; H05K 5/03; H05K 5/02; H02K 5/04

(52) U.S. Cl. CPC A61H 23/0263; B60N 2/976; A61H 1/005; H05K 7/1427; A61H 2201/1664; H05K 5/0217; H02K 5/04; A61H 2201/1215; H05K 5/03

(57) ABSTRACT

An ancillary unit of a motor vehicle, which may particularly be a massage device for a vehicle seat, includes an electrically conductive housing and a planar printed circuit board. A narrow side of the printed circuit board has an electrically conductive section, which is brought into electrical contact with the housing.

### CROSS-REFERENCE TO A RELATED APPLICATIONS

This application is the U.S. National Phase of PCT Application No. PCT/EP2017/075644, filed on Oct. 9, 2017, which claims priority to German Patent Application No. DE 10 2016 219 635.9, filed on Oct. 10, 2016, the disclosures of which are incorporated in their entirety by reference herein.

### TECHNICAL FIELD

The disclosure relates to an ancillary unit of a motor vehicle. The ancillary unit is, in particular, a massage device of a vehicle seat. The disclosure further relates to a vehicle seat of a motor vehicle.

### BACKGROUND

Motor vehicles have a number of ancillary units which do not directly serve to propel the motor vehicle. Convenience of the user of the motor vehicle is usually increased by these ancillary units. Ancillary units of this kind are, for example, electromotive window winders or electromotively operated tailgates/trunk lids. Here, an adjustment part, specifically a window or a tailgate/trunk lid, is driven by an electric motor, so that the adjustment part does not need to be manually moved. Further ancillary units of this kind are, for example, an electromotive seat adjustment system in which constituent parts of a seat, such as a backrest or the entire seat, is moved by an electric motor. Electromotively adjustable headrests are also known. A further ancillary unit is a massage device which is a constituent part of a vehicle seat. Here, upon activation, a specific region of the vehicle seat, such as a backrest or a portion of a backrest, is periodically adjusted. On account of this, the circulation of a user of the vehicle seat is stimulated and for this reason use of the motor vehicle is more comfortable. In this way, journeys of comparatively long duration may also be completed by the motor vehicle without the user becoming fatigued.

The ancillary units usually have an electronics system and/or electrical actuators. If the motor vehicle comprises a number of ancillary units of this kind, it is necessary to prevent said ancillary units from influencing one another. If this were not the case, other components could otherwise be negatively influenced during operation. For example, an ancillary unit could be unintentionally activated, and this could lead to injury to the user under certain circumstances. In addition, it is desirable to shield the user from any electromagnetic fields which are generated. In other words, it is necessary to increase the electromagnetic compatibility (EMC) of the ancillary units. A metal housing within which further constituent parts of the ancillary unit are arranged is usually used for this purpose. In order to achieve comparatively effective shielding, it is necessary for the housing to have comparatively few openings. Therefore, the individual constituent parts of the housing may have only comparatively low manufacturing tolerances, this increasing manufacturing costs.

### SUMMARY

A suitable ancillary unit of a motor vehicle and a particularly suitable vehicle seat of a motor vehicle, wherein in particular electromagnetic compatibility is increased and manufacturing costs are lowered, are disclosed herein.

The ancillary unit is a constituent part of a motor vehicle and, for example, an adjustment drive. During operation, an adjustment part is moved along an adjustment path by the adjustment drive. By way of example, the adjustment drive is an electromotive window winder, an electromotively driven tailgate/trunk lid or an electromotively operated door, such as a sliding door. As an alternative to this, the adjustment drive is an electromotive sliding roof or an electromotively operated folding top. In a further alternative, the ancillary unit is a pump, such as a lubricant pump for example. In particular, the ancillary unit is an oil pump, for example an engine oil pump or a transmission oil pump. In one alternative, the pump is a coolant pump or an air-conditioning compressor.

The ancillary unit is expediently an electromotive steering assistance system or an ABS or ESP unit. In a further alternative, the ancillary unit is an electromotive parking brake or some other electrical brake. The ancillary unit is particularly a constituent part of a vehicle seat and serves, for example, to adjust the seat or a portion of the seat, such as a backrest or a headrest. The ancillary unit is particularly a massage device of the vehicle seat. In other words, a massage function is executed during operation of the ancillary unit. Here, for example, a constituent part of the seat, such as the sitting surface or a backrest, is moved, in particular periodically.

The ancillary unit has an electrically conductive housing which is produced, in particular, from a metal, for example a steel or an aluminum, in particular pure aluminum or an aluminum alloy. Furthermore, the ancillary unit comprises a flat printed circuit board. In other words, the printed circuit board is arranged substantially in one plane and has a specific thickness perpendicularly in relation to the plane, which thickness is, in particular, less than 2 mm or 1 mm. By way of example, the printed circuit board is of cuboidal configuration. The printed circuit board has a narrow side which is perpendicular in relation to the plane of main extent of the printed circuit board and which delimits the periphery of the printed circuit board at least in sections. If the printed circuit board is, for example, of cuboidal configuration, the printed circuit board has four (4) narrow sides of this kind and also two front sides. The narrow side of the printed circuit board has an electrically conductive section. By way of example, the electrically conductive section is formed by a metal, for example an aluminum or a copper, that is to say in particular pure aluminum or pure copper or an aluminum alloy or copper alloy. The narrow side is expediently formed with the electrically conductive section. As an alternative, the narrow side has the electrically conductive section only in sections. The printed circuit board is arranged within the electrically conductive housing, and the electrically conductive section is electrically contact-connected to the housing. The section is expediently in direct mechanical contact with the housing.

Since the section at least partially forms an edge of the printed circuit board, only a comparatively small region of the printed circuit board is required for electrically contact-connecting the section to the housing, wherein the front side may be fitted with any electrical and/or electronic structures. A space requirement is reduced in this way. By way of example, the section is electrically contact-connected to the housing by a further component, wherein the component is attached, for example soldered, to the section and or to the housing for example. However, the section is particularly directly electrically contact-connected to the housing. Here, the section bears mechanically directly against the housing at least in sections. The manufacturing costs are reduced in this way.

The printed circuit board expediently has a ground connection which is electrically contact-connected to the section, for example by a conductor track of the printed circuit board. If the ground connection of the printed circuit board is electrically contact-connected to a ground connection of the motor vehicle during assembly, the housing is likewise contact-connected to ground, this improving the electromagnetic compatibility. In an alternative to this, the housing has a ground connection. If the ground connection of the housing is electrically contact-connected to a ground connection of the motor vehicle, the printed circuit board is likewise electrically contact-connected to the ground connection of the motor vehicle by the housing. In summary, only a single electrical contact-connection is required, this reducing assembly costs. The printed circuit board is pushed into the housing. In this way, the printed circuit board is protected by the housing, wherein the assembly is simplified.

The printed circuit board has a carrier composed of epoxy resin-reinforced glass fibers or epoxy resin-reinforced paper to which conductor tracks are attached. The conductor tracks are produced from copper and created, for example, by etching. The printed circuit board is a so-called interference-suppression printed circuit. In other words, the printed circuit board is used for providing an interference-suppression function. In particular, irradiation of electromagnetic waves is reduced or prevented by the printed circuit board during operation.

For example, a reaction by the ancillary unit on a possible on-board electrical system of the motor vehicle is reduced by the printed circuit board. Irradiated, field-bound electromagnetic interference phenomena are reduced by the printed circuit board. As a result, interference with further components of the motor vehicle which may be influenced by electromagnetic waves is reduced by the printed circuit board. To this end, the printed circuit board has at least one choke and/or one capacitor.

The housing is suitably of hollow-cylindrical configuration and consequently has a cylinder axis. Here, the cross section of the housing, perpendicularly in relation to the cylinder axis, is elliptical or round for example. The cross section is a regular polygon. The cross section of the housing is particularly substantially rectangular, for example square. The corners are particularly rounded or beveled. On account of a cross section of this kind, assembly is simplified and, owing to the rounded or beveled corners, robustness is increased. The printed circuit board is suitably arranged perpendicularly in relation to the cylinder axis. In other words, the profile of the narrow side of the printed circuit board is parallel in relation to the cylinder axis. Electrical contact-connection of the section to the housing is simplified in this way.

As an alternative or in combination with the above, the housing is a stamped-and-bent part. The housing is stamped from a steel, and the stamped piece is bent to form the housing. Here, the housing is suitably of hollow-cylindrical configuration, this facilitating manufacture. Two sides of the stamped piece are expediently joined to one another, wherein this is done, for example, in the region of one of the edges of the housing if the cross section of the housing is a polygon. The joining point of the two sides is particularly at a distance from the edges and, in particular, arranged substantially centrally between two adjacent corners of the cross section. The sides which are joined to one another run substantially parallel in relation to the cylinder axis, this increasing the robustness. By way of example, the two sides interengage by corresponding projections, in particular teeth, wherein any edges of the teeth are rounded for example, this further increasing the robustness. Manufacturing costs are reduced on account of the manufacture as a stamped-and-bent part.

The ancillary unit suitably has a cover by which the housing is closed. The cover is produced, for example, from a metal or a plastic. Ingress of foreign particles into the housing is prevented by the cover. By way of example, the cover is arranged at least partially within the housing. In other words, side walls of the housing project beyond the cover at least in sections. By way of example, the housing is closed by the cover at the end side, wherein, for example, the cover is fitted onto the end side. The cover may be produced from a metal. In particular, the cover is held by lugs of the housing.

The cover may be arranged parallel in relation to the printed circuit board. In particular, the cover extends substantially in a plane which is parallel in relation to the plane along which the printed circuit board extends. The cover is produced, for example, from plastic, in particular using an injection-molding process. The cover is expediently arranged perpendicularly in relation to the cylinder axis if the housing is of hollow-cylindrical configuration. By way of example, the cover is at a distance from the printed circuit board. However, the printed circuit board, by way of a front side, bears against the cover at least in sections. By way of example, the printed circuit board, in an edge region of the front side, bears against the cover, in an encircling manner. By way of example, the cover has a cutout in a central region, so that the printed circuit board does not bear against the cover in this region. This creates installation space for any electrical and/or electronic components of the printed circuit board, and keeps these at a distance from the cover. The printed circuit board is stabilized by the cover, and for this reason damage to the printed circuit board may be substantially precluded. In particular, the cover at least partially accommodates the printed circuit board. The printed circuit board is suitably fastened to the cover.

For assembly purposes, the printed circuit board is first attached to the cover and this combined unit is pushed into the housing, wherein leak tightness is created by the cover, and wherein the cover is located on the outer side of the printed circuit board. In this way, damage when the printed circuit board is inserted is substantially precluded on account of the cover. The cover expediently has a plug or at least a plug receptacle. In the assembled state, the on-board electrical system of the motor vehicle is electrically contact-connected to the plug or the plug receptacle. In other words, current is supplied to the ancillary unit by the plug or the plug receptacle.

By way of example, the housing has a notch. The notch is inwardly directed. In other words, the circumference, in particular the inner circumference, of the housing is reduced in the region of the notch. The printed circuit board bears mechanically against the notch. The printed circuit board bears mechanically directly against the notch. In other words, no further component is arranged between the printed circuit board and the housing. The section of the printed circuit board expediently bears against the notch. Here, the notch is provided, for example, by a v-shaped recess and created, for example, by embossing. In other words, the notch is an embossing. The profile of the notch is perpendicular in relation to the cylinder axis, if this is present. By way of example, for assembly purposes, the printed circuit board is pushed into the housing parallel in relation to the cylinder axis when the printed circuit board is oriented perpendicularly in relation to the cylinder axis. Here, holding with play is suitably created between the housing and the printed circuit board, this making insertion easier and preventing damage to the printed circuit board. The notch is configured in a circumferentially encircling manner. In this way, assembly is firstly simplified. In addition, it is always ensured that the section is in direct mechanical contact with the notch, this increasing the robustness. In addition, it is not necessary for the printed circuit board to be oriented in a particular way with respect to the notch.

In the assembled state, a press-fit is expediently created between the printed circuit board and the housing. In other words, a force-fitting connection is created between the printed circuit board and the housing. In this way, a vibration of the ancillary unit the electrical contact-connection between the section and the housing is also ensured. A force-fitting connection is created between the section and the notch. This is expediently done by the notch. An inner region of the housing is reduced at a defined point by the notch, so that the printed circuit board is held by the notch in a comparatively simple manner. Here, for assembly purposes, the printed circuit board is guided as far as the region of the notch, wherein an application of force is increased only in this region. In addition, comparatively few additional components are required for assembly purposes. In addition, an electrical contact-connection is comparatively secure on account of the press-fit via the notch. In other words, the electrical contact-connection does not become detached even in the event of vibration of the ancillary unit.

The section encircles the edge of the printed circuit board. In other words, all of the narrow sides of the printed circuit board are formed by the section, and the rest of the carrier of the printed circuit board is surrounded circumferentially, in particular completely, by the section. Assembly is simplified in this way since the electrical contact-connection with the housing is always present irrespective of the orientation of the printed circuit board with respect to the housing. Here, the housing expediently has the encircling notch. Assembly is further simplified in this way. In addition, the housing and the printed circuit board are electrically contact-connected to one another in a circumferentially encircling manner, this further increasing the electromagnetic compatibility.

By way of example, the section is created by a conductor track of the printed circuit board, which conductor track is bent over in particular. As an alternative to this, the section is created, for example, by a metal strip which is attached, for example soldered, to a further constituent part of the printed circuit board. The section is expediently configured in the form of a clip if the section forms a comparatively large edge region of the printed circuit board. However, the section is particularly created by coating. In other words, the section is a coating. Manufacture is simplified in this way.

The printed circuit board expediently has an electrically conductive layer which is, in particular, parallel in relation to the front side. In other words, the layer is parallel in relation to the plane within which the printed circuit board substantially extends. The layer is suitably a copper layer. The printed circuit board is at least a two-layer printed circuit board, and one of the layers corresponds to the electrically conductive layer. The (electrically conductive) layer is electrically contact-connected to the section. In this way, the layer has substantially the same electrical potential as the housing. All of the other electrical and/or electronic components of the printed circuit board are expediently offset inward into the housing with respect to the layer. In this way, a shielding is provided by the layer, wherein the layer is at the same electrical potential as the housing. In particular, the layer is coated, on the front side, with an insulator, such as epoxy resin for example. In other words, one of the front sides of the printed circuit board is formed either by the layer or by the electrical insulator.

The layer is expediently intact. In other words, no conductor track or the like is provided by the layer. However, here, the layer expediently has openings through which, for example, connection plugs, for example pins, are guided and by which electrical contact-connection of any components which are arranged within the housing is therefore possible. Comparatively simple and cost-effective electrical shielding in the region of any opening of the housing is provided by the layer, wherein standard components may be used, this reducing manufacturing costs. In particular, the section is electrically contact-connected directly to the layer. In other words, there are no further electrical components between the layer and the section.

The printed circuit board has an electrical and/or electronic component. The electrical component is, for example, a resistor, a coil or a capacitor. The electronic component is, for example, an integrated circuit, such as a microchip. The electrical or electronic component is electrically contact-connected to the section, for example by a conductor track of the printed circuit board. In particular, the conductor track is created by a layer. Here, the conductor track is created, in particular, from a layer which is separated, in order to provide the individual conductor tracks. In this way, it is possible to connect the electrical or electronic component to ground if the housing is electrically connected to ground, this firstly reducing the space requirement and secondly simplifying assembly.

The ancillary unit expediently comprises an electric motor which is electrically contact-connected to the printed circuit board. The electric motor is, for example, a brush-type electric motor, such as a brush-type DC motor. As an alternative to this, the electric motor is a brushless motor, for example a brushless DC motor (BLDC). The electric motor is expediently a synchronous motor. In particular, current is supplied to the electric motor by the printed circuit board. As an alternative to or in combination with this, interference of any electric current which is used to supply current to the electric motor is suppressed by the printed circuit board, wherein the interference which may occur is introduced into the current, for example, on account of the operation of the electric motor. The electric motor is arranged, in particular, in the housing, so that electromagnetic fields which are created by the electric motor are shielded by the housing, this increasing the electromagnetic compatibility. Here, the housing of the ancillary unit particularly supports any housing of the electric motor. In summary, the ancillary unit is an electromotive ancillary unit. If the printed circuit board has the electrically conductive layer which is electrically contact-connected to the section, any electrical and/or electronic components are located between the layer and the electric motor, so that any electromagnetic fields which are created by the electrical and/or electronic components of the printed circuit board are comparatively efficiently shielded by the layer.

The vehicle seat is a constituent part of a motor vehicle and has a massage device. The massage device comprises an electrically conductive housing with a flat printed circuit board arranged in said housing. A narrow side of the printed circuit board has an electrically conductive section which is electrically contact-connected to the housing.

### BRIEF DESCRIPTION OF THE DRAWINGS

An exemplary embodiment of the disclosure will be explained in more detail below with reference to a drawing, in which:

FIG. 1 shows, in a schematically simplified form, a vehicle seat comprising a massage device,

FIG. 2 shows a perspective view of the massage device, and

FIGS. 3 and 4 each show a perspective view of an exploded illustration of the massage device.

Parts which correspond to one another are provided with the same reference symbols throughout the figures.

### DETAILED DESCRIPTION

As required, detailed embodiments of the present disclosure are disclosed herein; however, it is to be understood that the disclosed embodiments are merely exemplary and that the embodiments described herein may take on other various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present disclosure.

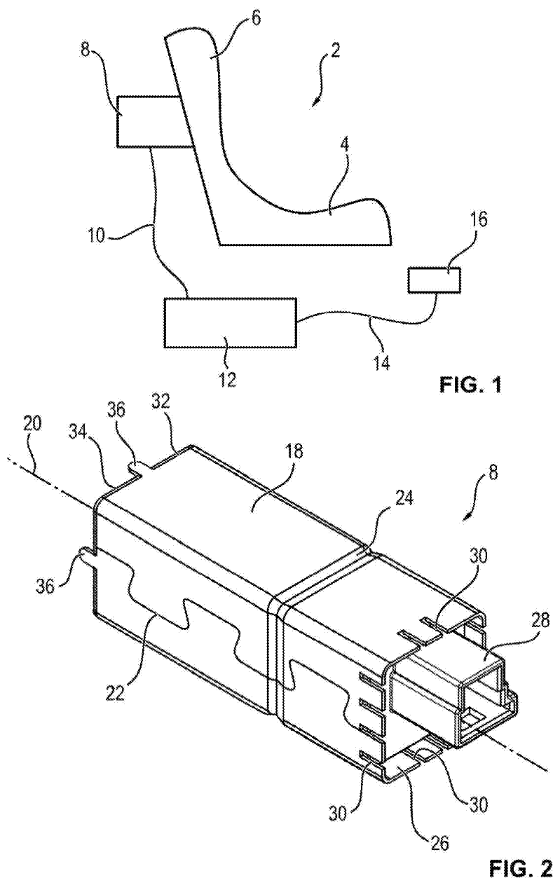

FIG. 1 shows, in a schematically simplified form, a vehicle seat 2 of a motor vehicle, which vehicle seat comprises a sitting surface 4 and a backrest 6. An ancillary unit 8 in the form of a massage device is attached to the backrest 6 of the vehicle seat 2. The ancillary unit 8 is connected to a control unit 12 by a first signal line 10, which control unit is, in turn, connected to a switch 16 by a second signal line 14. When the switch 16 is operated by the user of the motor vehicle 2, the control unit 12 is activated and the massage device 8 is actuated by the control unit 12. In this process, the backrest 6 is moved in the region of the massage device 8, wherein, for example, the surface of the backrest 6 is periodically pushed out.

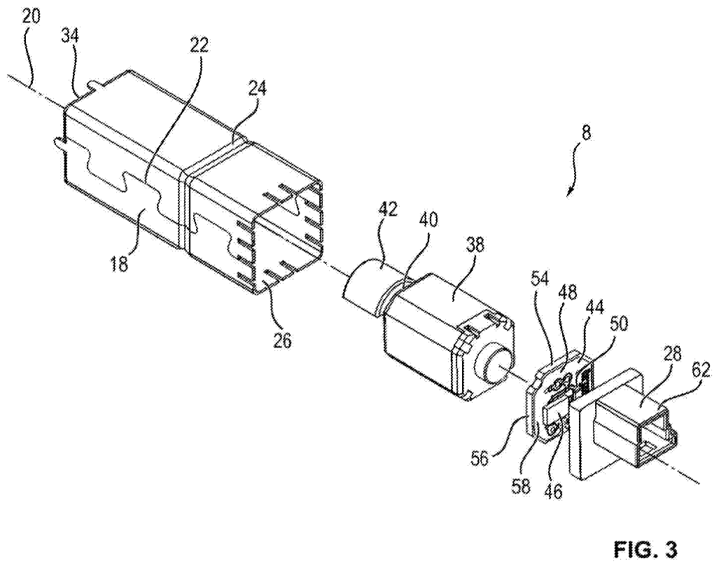

FIG. 2 shows a perspective view of the ancillary unit 8. The ancillary unit 8 has a housing 18 which is of substantially hollow-cylindrical configuration and extends along a cylinder axis 20. The housing 18 is stamped out of an aluminum as a stamped-and-bent part, and for this reason the housing 18 is electrically conductive. The stamped piece is bent to form the hollow-cylindrical shape, wherein the cross section of the housing 18 is square perpendicular in relation to the cylinder axis 20. The corners of the square are rounded. The sides 22 of the stamped piece which are joined to one another during manufacture of the housing 18 have projections and corresponding recesses, so that the two sides 22 which are joined to one another interengage in an interlocking manner, this leading to a comparatively high stability of the housing 18.

The housing 18 further has an inwardly directed notch 24 which is arranged perpendicularly in relation to the cylinder axis 20 and is configured so as to encircle the housing 18. The notch 24 has a V-shaped cross section in a section parallel in relation to the cylinder axis 20. The inner and outer circumference of the housing 18 are reduced by the notch 24.

A cover 28 which is composed of a plastic and is created using an injection-molding process is pushed into one of the end sides 26 of the housing 18. In the process, the cover 28 is pushed into the housing 18 to a certain extent and closes the housing 18 on this side. In this region, the housing 18 has a number of slots 30 which run parallel in relation to the cylinder axis 20 and which extend as far as the position of the cover 28. The further end side 32 of the housing is covered by a second cover 34 which is created from the same material as the housing 18 by stamping. The second cover 34 has the same cross section as the housing 18 and completely closes the further end side 32. The second end side 32 has lugs 36 which project in the axial direction, which is parallel in relation to the cylinder axis 20, and project beyond the second cover 34. The second cover 34 has corresponding cutouts in these regions. The second cover 34 is fastened to the housing 18 by bending over the lugs 36. Here, each of the sides of the housing 18 comprises one of the total of four lugs 36 in each case.

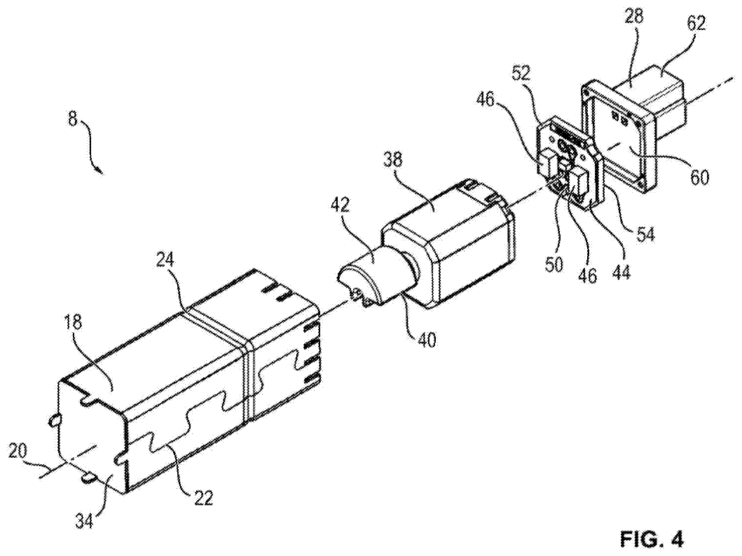

FIG. 3 and FIG. 4 each show an exploded illustration of the ancillary unit 8, wherein the second cover 34 is fitted to the housing 18 in each case. An electric motor 38 is arranged between the cover 28 and the second cover 34 in the housing 18, a weight 42 being fastened in a rotationally fixed manner to the drive shaft 40 of said electric motor. The weight 42 is located on that side of the electric motor 38 which faces the second cover 34. The weight 42 is configured in the shape of a half-moon and therefore has an unbalance. Rotation of the weight 42 by the drive shaft 40 causes a shaking movement of the housing 18, this leading to a massage functionality of the ancillary unit 8 since the backrest 6 is rhythmically moved. In the assembled state, a play-fit or a press-fit is created between the electric motor 38 and the housing 18.

A printed circuit board 44 is positioned on that side of the electric motor 38 which is situated opposite the weight 42. The printed circuit board 44 is of flat configuration, wherein the plane of extent of the flat printed circuit board 44 is arranged perpendicularly in relation to the cylinder axis 20. In other words, the printed circuit board 44 is arranged perpendicularly in relation to the cylinder axis 20. Current is supplied to the electric motor 38 by the printed circuit board 44, and the electric motor 38 is electrically contact-connected to the printed circuit board 44, for example by a motor carrier which is not shown here. The printed circuit board 44 has a number of electrical and/or electronic components 46 which are fastened to a carrier 48 of the printed circuit board 44. The carrier 48 comprises an epoxy resin which is reinforced with glass fibers and to which conductor tracks 50 which are composed of copper are attached. The conductor tracks 50 are created from individual copper layers. Furthermore, a substantially intact layer 52 is embedded within the carrier 48, said layer being created substantially from a copper and extending substantially over the entire extent of the printed circuit board 44 perpendicularly in relation to the cylinder axis 20. The layer 52 is electrically contact-connected to an electrically conductive section 54 which is formed in a circumferentially encircling manner around the carrier 48 and therefore forms substantially all of the narrow sides 56 of the printed circuit board 44. The section 54 is created by coating the carrier 48 on the narrow side 56 of said carrier. At least one of the electrical and/or electronic components 46 is electrically contact-connected to the section 54 by one of the conductor tracks 50.

In the assembled state, an edge region of the front side 58 of the printed circuit board 44 bears against the cover 28 which is arranged substantially parallel in relation to the printed circuit board 44. There is a cutout 60 in a central region of the cover 28, so that the cover 28 is at a distance from the electrical and/or electronic components 46 which form the front side 58 in this region. The cover 28 itself has a plug connection (plug receptacle) 62 which is directed away from the printed circuit board 44. In the assembled state, the signal line 10 is fastened to the plug connection 62. Furthermore, the plug connection 62 comprises electrical contacts, not illustrated in any detail, which are electrically contact-connected to the printed circuit board 44, so that current is supplied to the printed circuit board 44 by the signal line 10. The printed circuit board 44 serves for interference suppression, for which reason interfering noise which is introduced into a possible electric current, so-called ripple which is produced, for example, on account of the operation of the electric motor 38, is not conducted to the control unit 12.

For assembly purposes, the printed circuit board 44 is pushed into the housing 18, wherein a play-fit is created between the housing 18 and the printed circuit board 44 in the region of the end side 26. In the assembled state, the printed circuit board 44 is pushed further into the housing 18 as far as the notch 24, so that the printed circuit board 44 bears mechanically directly against the inwardly directed notch 24. Here, a force-fitting connection is created between the encircling notch 24 and the section 54 which is configured in an encircling manner, this securely holding the printed circuit board 44. During assembly, the printed circuit board 44 is stabilized by the cover 28, so that damage to the printed circuit board 44 is precluded. On account of the section 54 bearing directly against the housing 18, said section and housing are electrically contact-connected to one another. Consequently, the housing 18 has the same electrical potential as the section 54 which is electrically contact-connected to the plug connection 62 of the cover 28 by a conductor track 50, not shown in any detail, of the printed circuit board 44. In the assembled state, this portion of the plug connection 62 is electrically contact-connected to ground of the motor vehicle, so that both the section 54, the layer 52, the housing 18 and the second cover 34 each have ground as the electrical potential. Consequently, the electric motor 38 and also the electrical and/or electronic components 46 which face the electric motor 38 are shielded, this increasing the electromagnetic compatibility (EMC).

In summary, the electromagnetic compatibility is increased in the ancillary unit 8, wherein the printed circuit board 44 and the housing 18 are electrically contact-connected without an additional connection technique, such as soldering for example. An electrical connection to the housing 18 is created by the electrically conductive section 54, which substantially constitutes the edge of the printed circuit board 44, by the notch 24. Therefore, the layer 52 and the housing 18 and also the second cover 34 form a completely closed shield.

The disclosure is not restricted to the exemplary embodiment described above. Rather, other embodiments may be derived by a person skilled in the art from said exemplary embodiment, without departing from the subject matter of the disclosure. In particular, all of the individual features described in connection with the exemplary embodiment may be further be combined with one another in a different way, without departing from the subject matter of the disclosure.

While exemplary embodiments are described above, it is not intended that these embodiments describe all possible forms of the disclosure. Rather, the words used in the specification are words of description rather than limitation, and it is understood that various changes may be made without departing from the spirit and scope of the disclosure. Additionally, the features of various implementing embodiments may be combined to form further embodiments.

### LIST OF REFERENCE SYMBOLS

2 Vehicle seat

4 Sitting surface

6 Backrest

8 Ancillary unit

10 First signal line

12 Control unit

14 Second signal line

16 Switch

18 Housing

20 Cylinder axis

22 Sides which are joined to one another

24 Notch

26 End side

28 Cover

30 Slot

32 Further end side

34 Second cover

36 Lug

38 Electric motor

40 Drive shaft

42 Weight

44 Printed circuit board

46 Electrical or electronic component

48 Carrier

50 Conductor track

52 Layer

54 Section

56 Narrow side

58 Front side

60 Cutout

62 Plug connection

1. An ancillary unit of a motor vehicle, in particular a massage device of a vehicle seat, comprising an electrically conductive housing and comprising a flat printed circuit board arranged in the housing, wherein a narrow side of the printed circuit board has an electrically conductive section which is electrically contact-connected to the housing.

2. The ancillary unit of claim 1, wherein the housing has a hollow-cylindrical configuration and the printed circuit board is arranged perpendicularly in relation to the cylinder an axis of the hollow-cylindrical configuration.

3. The ancillary unit of claim 1 further comprising a cover arranged parallel in relation to the printed circuit board, wherein the cover at least partially engages and supports a front side of the printed circuit board.

4. The ancillary unit of claim 1, wherein the housing has an inwardly directed notch that engages and supports the printed circuit board.

5. The ancillary unit of claim 4, wherein the notch circumferentially encircles and engages the electrically conductive section.

6. The ancillary unit of claim 1, wherein the electrically conductive section encircles an edge of the printed circuit board.

7. The ancillary unit of claim 1, wherein the electrically conductive section is a coating.

8. The ancillary unit of claim 1, wherein the printed circuit board has an electrically conductive layer which is electrically contact-connected to the electrically conductive section.

9. The ancillary unit of claim 1, wherein printed circuit board has an electrical component which is electrically contact-connected to the electrically conductive section.

10. The ancillary unit of claim 1 further comprising an electric motor disposed within the housing, wherein the electric motor is electrically contact-connected to the printed circuit board.

11. (canceled)

12. The ancillary unit of claim 1, wherein the housing is a stamped-and-bent part.

13. The ancillary unit of claim 5, wherein a force-fitting connection is created between the electrically conductive section and the notch.

14. A massaging device for a vehicle seat comprising:
an electrically conductive housing defining a cavity and an internal surface, wherein the housing is secured to the vehicle seat; and
a printed circuit board disposed within the cavity, the printed circuit board having an electrically conductive outer peripheral surface that contacts and establishes and an electrical connection with the internal surface of the housing.

15. The massaging device of claim 14, wherein the housing is cylindrical in shape and extends along an axis, and wherein a front side of the printed circuit board is perpendicular to the axis.

16. The massaging device of claim 15 further comprising a cover that is at least partially disposed within the cavity, wherein the cover supports and engages the front side of the printed circuit board.

17. The massaging device of claim 16, wherein a press-fitting connection is formed between the outer peripheral surface of the printed circuit board and the internal surface of the housing.

18. The massaging device of claim 16 further comprising an electric motor disposed within the cavity, wherein the electric motor contacts and establishes an electrical connection with the printed circuit board.

19. The massaging device of claim 18, wherein the printed circuit board is disposed between the electric motor and the cover.

20. The massaging device of claim 14, wherein the housing has an inwardly directed notch that engages and supports the outer peripheral surface of the printed circuit board.

21. A vehicle seat having a massaging device, the massaging device having an electrically conductive housing and a printed circuit board disposed within the housing, the printed circuit board having an electrically conductive outer surface that contacts and establishes and an electrical connection with an internal surface of the housing.
